(19) United States
(12) Patent Application Publication
(10) Pub. No.: US 2006/0032737 A1
(43) Pub. Date: Feb. 16, 2006

(54) Magnetron sputtering device, a cylindrical cathode and a method of coating thin multicomponent films on a substrate

(75) Inventor: Michael Liehr, Feldatal (DE)

Correspondence Address: SHERIDAN ROSS PC, 1560 BROADWAY, SUITE 1200, DENVER, CO, 80202, US

(73) Assignee: Applied Films GmbH & Co. KG, Alzenau (DE)

(21) Appl. No.: 11/170,742

(22) Filed: Jun. 28, 2005

(30) Foreign Application Priority Data
Aug. 10, 2004 (EP) 04 018 926.8

(51) Int. Cl. C23C 14/32

(52) U.S. Cl. 204/192.12; 204/298.21; 204/298.22; 204/298.12

(57) ABSTRACT

The invention relates to a magnetron sputtering device particularly comprising at least one vacuum chamber and being intended for the coating of multicomponent films on a substrate by means of magnetron co-sputtering; said device is provided with a cylindrical cathode (1, 1′) mounted rotatably around the axial longitudinal shaft and is further provided with a magnetic system arranged inside the cylindrical cathode (1, 1′). The cylindrical cathode (1, 1′) includes at least two segments (2, 2′, 3, 3′, 4, 4′, 5, 5′) having different target materials. In addition, the invention relates to a method of coating multicomponent films on a substrate by way of magnetron co-sputtering in a vacuum coating system.

The invention relates to a magnetron sputtering device, a cylindrical cathode and a method of coating thin multicomponent films on a substrate in accordance with the preambles of claims 1, 5 and 10 respectively.

The use of a magnetron sputtering devices, i.e. targets with magnetic arrays, which make it possible to sputter in the direction of a substrate, have been known for some time in vacuum coating systems for coating different types of substrate; moreover, these devices are suitable for coating that involves a very wide variety of coating materials. Such vacuum coating systems include working chambers in which coating takes place. These vacuum chambers have a base pressure in a required vacuum range which, in accordance with the process parameters, prevents, in particular, contamination while the film is being deposited. During coating, the vacuum chambers have a working pressure that may be well above the base pressure and which is caused by the process gas.

Magnetron sputtering devices fitted with cylindrical magnetrons, in particular, exhibit an advantageously high target-material utilization rate and a long target service life. Use is made of cylindrical cathodes which are structured completely from a target material, as are described, for example, in DD 217 964. Use can, however, also be made of carrier tubes which are provided with a circumferentially applied film of target material, as described in U.S. Pat. No. 4,356,073. A uniform rotation of the cylindrical cathode causes the target material to be eroded evenly on the cylindrical cathode surface, because locally concentrated sputtering and hence the formation of grooves are prevented.

The co-sputtering technique is frequently employed to coat multicomponent films on a substrate, for instance in the manufacture of photovoltaic absorbers. The individual components of the film are simultaneously sputtered from different targets and coated on a substrate. It is on the substrate that these components are intermingled to form a multicomponent film. Co-sputtering can be brought about in various ways. For instance, several separate targets with varying material components can be alternately arranged in line. As a function of the desired film thickness, the substrate is then guided past these targets at such a speed that the individual material components are superimposed on the substrate, thus forming the multicomponent film. Largely homogeneous films can be formed in this way. This technique does suffer from the drawback that the vacuum coating system is relatively expensive, as a large number of individual cathodes and an extensive vacuum chamber will be required.

It is also, however, possible to make use of just one target that is composed of several regions with varying material components. In this case, the substrate is usually fixed in position, with the individual components being simultaneously sputtered and impacting the substrate at the same time in order to form the multicomponent film. The disadvantage of this technique is that the targets are complex and the costs incurred are high. Furthermore, impurities can be incorporated into the multicomponent film, because the individual regions are usually combined by means of adhesive into a single target which likewise undergoes the sputtering process. In addition, these multicomponent targets are planar. Such planar targets do, however, permit only a low target utilization and they exhibit a relatively large area of redeposition. The large redeposition zones cause process-related problems and lead to a poorer quality of film on the substrate.

The present invention's object is therefore to make available a magnetron sputtering device, a cylindrical cathode and a method that can be used to coat multicomponent films on a substrate, with the drawbacks encountered in the prior art being overcome. It is particularly the present invention's object to make a compact vacuum coating system possible and thus to lower the costs of such a system.

In accordance with the invention, this object is solved by a magnetron sputtering device according to claim 1, a cylindrical cathode according to claim 5 and a method according to claim 10. Advantageous embodiments of the invention are characterized by the features contained in the dependent claims.

The magnetron sputtering device according to the invention, which device comprises in particular at least one vacuum chamber and is intended for coating multicomponent films on a substrate, is provided with a cylindrical cathode that is mounted rotatably around the longitudinal axis and with a magnetic system. The magnetic system is positioned within the cylindrical cathode. The cylindrical cathode comprises at least two segments having different target materials, and the magnetron sputtering device has means for rotating the cylindrical cathode and means for shifting the substrate, with the help of which means the cylindrical cathode is rotated around the longitudinal axis at a rotational speed that is chosen to be sufficiently large in relation to the speed of the substrate when it is shifted, thus depositing a multicomponent film on the substrate. This magnetron sputtering device can be designed to be very compact, in contrast to a magnetron sputtering device structured by means of many in-line targets. The vacuum coating systems can be clearly reduced in size by using the magnetron sputtering device according to the invention. As a result, it is possible to lower the cost price and maintenance costs, which after all do not just include the pure operating costs, but also the costs for the necessary floor space. In contrast to a planar multicomponent target, impurities caused by adhesives are avoided. Moreover, the target utilization is greater and the redeposition zone is smaller, thereby achieving a higher quality of film.

The means for shifting the substrate are preferably adapted so as to shift the substrate in a perpendicular fashion relative to the longitudinal axis of the cylindrical cathode. In this way, the deposited multicomponent film is able to exhibit a high degree of homogeneity.

The magnetron sputtering device expediently comprises a plurality of cylindrical cathodes. Such a magnetron sputtering device can be used to coat multicomponent films on substrates that cover very large surface areas. If different, successive films are to be coated, it may be advantageous for the magnetron sputtering device to comprise a plurality of different cylindrical cathodes that have varying combinations of target materials.

The cylindrical cathode as specified by the invention and which may be used particularly in the above-described magnetron sputtering device comprises at least two segments having different target materials. It is an advantage if the individual segments are designed as cylindrical segments. In addition, however, it may be necessary to design the segments in a planar fashion at their outer sides whenever it is not possible to coat the segments by means of plasma injection, for instance. In the plasma injection technique, ceramic material compositions, for example, cannot always be coated on a cylindrical target with the requisite material density and homogeneity.

A large target surface area is available for the individual materials, particularly when the individual segments adjoin one another directly. The individual segments may be positioned on a carrier tube if support is required, for example in the case of thin segments or segments that exhibit mechanically inadequate stability.

As a general principle, all metals, metal oxides and materials from which unsupported segments cannot, on account of production problems, be manufactured (which especially include ITO, IZO, ZAO, chromium or tungsten) can be coated on carrier tubes. Examples of production techniques suitable for this purpose include hot isostatic pressing, plasma injection and bonding or affixing. To make solid targets, use can, however, be made of any metals from which unsupported segments can be produced as a result of, for example, cutting, drawing, milling, bending or rolling, whereby the segments can be joined together to form a single target by means of, for example, soldering or welding, as well as by way of mechanical solutions such as dovetail guides. This will particularly coat to tin, zinc, nickel, copper, aluminium, silver, gold, platinum, molybdenum, titanium and neodymium.

Normal dimensions for the cylindrical cathode targets are lengths of 500 to 4,500 mm, diameters of 100 to 300 mm and wall thicknesses of 1 to 50 mm.

It is expedient for the widths of the individual segments to be adapted to the desired stoichiometry of the multicomponent film in relation to the longitudinal cylindrical-cathode axis as a function of the sputtering yield of the respective target material. As a result, the cylindrical cathode within the magnetron sputtering device can be operated at a constant rotational speed.

The method according to the invention for coating multicomponent films on a substrate by way of magnetron co-sputtering within a vacuum coating system is performed as follows. A cylindrical cathode that is mounted rotatably around the axial longitudinal direction and which comprises at least two segments with different materials is rotated around the longitudinal axis above an internal magnetic system while the multicomponent film is being coated on the substrate. At the same time, the substrate is guided past the cylindrical cathode at a certain speed in a direction that is perpendicular to the longitudinal cylindrical axis. This substrate speed is chosen as a function of the sputtering yield and of the distance of the cylindrical cathode from the substrate in such a way that the multicomponent film obtains a desired thickness on the substrate. The cylindrical cathode's rotational speed is chosen as a function of the substrate speed such that the individual target segments with the different material components are sputtered in quick succession. The cylindrical cathode's high rotational speed in relation to the substrate speed causes the individual material components to be locally superimposed on the substrate and to be intermixed, thereby depositing a multicomponent film on the substrate.

Compared to the techniques hitherto employed, the relatively slow dislocation of the substrate relative to the rapid rotation of the cylindrical cathode allows film deposition to occur much more homogeneously, and the film thickness can thus be adjusted with greater accuracy.

The stoichiometry of the multicomponent film can be expediently adjusted in that the widths of the individual segments are designed to vary in relation to the longitudinal cylindrical axis as a function of the sputtering yield of the respective target material, and the cylindrical cathode within the magnetron sputtering device is operated at an even, that is to say constant rotational speed.

The even rotational speed of the cylindrical cathode expediently ranges from 5-20 rpm and preferably at 10 rpm. It must be borne in mind here that the optimum choice of rotational speed will depend on the number of target segments on the cylindrical cathode. The lower this number is, the higher the rotational speed has to be chosen in order to ensure that the individual components are sufficiently intermixed and hence to make sure that the quality of the film is high.

Several cylindrical cathodes arranged within the magnetron sputtering device are advantageously used for film deposition, especially as concerns substrates that have large substrate widths in relation to the substrate movement, as well as regarding large substrate lengths. This makes it possible to speed up film deposition. If different films are to be coated on a substrate, it may, moreover, be advisable to coat the various multicomponent films in two or more vacuum chambers.

Compared to the use of a plurality of in-line targets, the aforementioned invention enjoys the advantage that the size of the facility is greatly reduced by designing the target as a compact multicomponent target. The coating system's cost price and maintenance costs can thereby be reduced. In contrast to the use of a complex, planar multicomponent target, the cylindrical cathode according to the invention is easier to manufacture and hence more cost-effective. Furthermore, a higher target-utilization rate and much lower redeposition are achieved, and the film characteristics are improved.

An exemplary embodiment will now be explained in more detail below on the basis of a drawing in which the following is depicted:

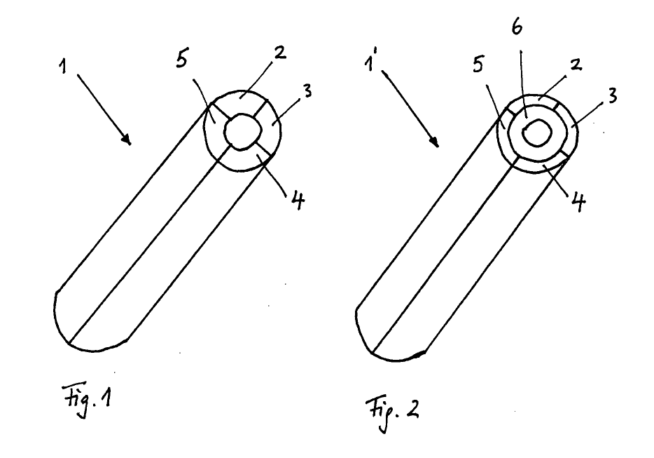

FIG. 1 shows a perspective view of a cylindrical cathode as specified by the invention and which is structured completely from target material, and

FIG. 2 shows a perspective view of a cylindrical cathode as specified by the invention and the target materials of which are coated on a carrier tube.

The cylindrical cathode 1 as specified by the invention and in accordance with FIG. 1 is designed as a cylindrical tube. The cylindrical cathode 1 is completely composed of target material and comprises two target materials in the case depicted. Each target material is located in two separate cylindrical segments 2, 4 and 3, 5 which face one another. The four segments 2, 3, 4 and 5 each have a circular arc of 90° and a common length that corresponds to the length of the cylindrical cathode 1, 1′. To form the cylindrical cathode 1, the segments are directly joined together by means of welding, soldering or mechanical solutions such as dovetail guides.

If the material's properties or the production process do not permit the cylindrical cathode to be directly structured from target material, the cylindrical cathode 1′ is formed simply by coating different target material to a carrier tube 6, as shown in FIG. 2. The individual cylindrical segments 2′, 3′, 4′ and 5′ may be coated on a carrier tube 6 for example by means of plasma injection. The segments adjoin one another directly and have an identical length and circular arcs of 90°.

For use in a magnetron sputtering device according to the invention, the cylindrical cathodes 1 and 1′ are provided with suitable means (not depicted) which enable the cylindrical cathodes 1 and 1′ to be mounted via a known magnetic system positioned within their interior and via an axially symmetric rotational movement around their longitudinal axis.

To coat a multicomponent film, the substrate is moved, at a speed adapted to the desired film thickness of the film to be coated, in a manner perpendicular to the longitudinal axis of the cylindrical cathode 1. At the same time, the cylindrical cathode 1 is rotated. Every time the cylindrical cathode 1 rotates, the cylindrical segments 2, 3, 4 and 5 are guided past the internal magnetic system and material is sputtered out of these cylindrical segments in quick succession. This material is coated on the substrate with the assistance of the known magnetron effect. Since the rotational speed of the cylindrical cathode 1 is much greater than the speed of the substrate, the individual material components are superimposed locally on the substrate. This superimposition causes the individual material components to be intermixed and a hybrid component film is formed on the substrate.

Of course, two or more segments can be used to form the cylindrical cathodes 1 and 1′ if required. If the rotational speed of the cylindrical cathodes 1 and 1′ remain even, the stoichiometry of the multicomponent film can also be adjusted in that the width of the cylindrical segments is correspondingly adjusted as a function of the sputtering yield of the individual material components. It is, however, also conceivable for the stoichiometry to be adjusted via an uneven rotational speed.

As far as substrates which cover a large surface area are concerned, a plurality of cylindrical cathodes 1, 1′ can be used within a magnetron sputtering device. In a process chain, several vacuum chambers that have magnetron sputtering devices which are each provided with different cylindrical cathodes 1, 1′ with different combinations of target materials can in turn be arranged sequentially in order to coat a succession of different multicomponent films on a substrate.

The present invention therefore makes it possible to coat multicomponent films on substrates by means of magnetron sputtering in vacuum coating systems, the size of which has been reduced greatly. The use of the cylindrical cathode 1, 1′ achieves a high target utilization and a high quality of film.

1. A magnetron sputtering device, particularly comprising at least one vacuum chamber, for coating thin multicomponent films on a substrate, said device having a cylindrical cathode rotatably mounted around the longitudinal axis and having a magnetic system disposed within said cylindrical cathode, said cylindrical cathode comprising at least two segments having different target materials, and said magnetron sputtering device having means for rotating said cylindrical cathode and means for shifting the substrate relative to said cylindrical cathode, characterized in that said means for rotating said cylindrical cathode are adapted to rotate said cylindrical cathode essentially continuously at a speed which depends on the substrate speed such that said target materials are intermixed on said substrate, thereby depositing a multicomponent film on said substrate by means of magnetron co-sputtering.

2. A magnetron sputtering device in accordance with claim 1, characterized in that said means for shifting said substrate are adapted to shift said substrate in a direction perpendicular to the longitudinal shaft of said cylindrical cathode.

3. A magnetron sputtering device in accordance with claim 1, characterized in that said magnetron sputtering device comprises a plurality of cylindrical cathodes.

4. A magnetron sputtering device in accordance with claim 3, characterized in that said cylindrical cathodes comprise different combinations of target materials.

5. A magnetron sputtering device in accordance with claim 1, characterized in that said segments of said cylindrical cathode are designed as cylindrical segments.

6. A magnetron sputtering device in accordance with claim 1, characterized in that said segments of said cylindrical cathode adjoin one another directly.

7. A magnetron sputtering device in accordance with claim 1, characterized in that said segments of said cylindrical cathode are disposed on a carrier tube.

8. A magnetron sputtering device in accordance with claim 1, characterized in that the widths of said segments of said cylindrical cathode are adapted to the desired stoichiometry of the multicomponent film relative to the longitudinal shaft of said cylindrical cathode as a function of the sputtering yield of the respective target material.

9. A method of coating thin multicomponent films on a substrate in a vacuum coating system by means of magnetron co-sputtering, having a cylindrical cathode rotatably mounted around the axial longitudinal shaft and positioned within a magnetron sputtering device, characterized in that
said cylindrical cathode comprises at least two segments having different materials and is rotated around the longitudinal shaft above the internal magnetic system while the films are being coated on the substrate,
said substrate is guided past said cylindrical cathode during sputtering,
the substrate speed is chosen as a function of the sputtering yield and the distance of said cylindrical cathode from said substrate in such a way that said multicomponent film obtains a desired thickness on said substrate, and
the rotational speed of said cylindrical cathode is chosen as a function of the substrate speed in such a way that said individual target segments are sputtered in rapid succession, and the various material components are superimposed and intermixed locally on said substrate, thereby depositing a multicomponent film on said substrate.

10. A method in accordance with claim 9, characterized in that said cylindrical cathode comprises different combinations of target materials.

11. A method in accordance with claim 9, characterized in that said substrate is moved perpendicular to the longitudinal shaft of said cylindrical cathode.

12. A method in accordance with claim 9, characterized in that said cylindrical cathode is moved at an even rotational speed.

13. A method in accordance with claim 12, characterized in that the rotational speed of said cylindrical cathode is 5-10 rpm.

14. A method in accordance with claim 9, characterized in that the stoichiometry of said multicomponent film is adjusted in that the widths of said different material segments are chosen to vary as a function of the sputtering yield.

15. A method in accordance with claim 9, characterized in that various multicomponent films are coated on said substrate by a plurality of cylindrical cathodes positioned within said magnetron sputtering device.

16. A method in accordance with claim 9, characterized in that various multicomponent films are coated on said substrate by a plurality of magnetron sputtering devices positioned in at least two vacuum chambers within said coating system, said substrate passing through said individual vacuum chambers without interrupting the vacuum.

17. A method in accordance with claim 9, characterized in that said segments of said cylindrical cathode are designed as cylindrical segments.

18. A method in accordance with claim 9, characterized in that said segments of said cylindrical cathode adjoin one another directly.

19. A method in accordance with claim 9, characterized in that said segments of said cylindrical cathode are disposed on a carrier tube.
